(19) United States
(12) Patent Application Publication
(10) Pub. No.: US 2026/0282882 A1
(43) Pub. Date: Sep. 17, 2026

(54) MEMORY CIRCUIT, SEMICONDUCTOR DEVICE, AND ELECTRONIC DEVICE

(71) Applicant: SONY SEMICONDUCTOR SOLUTIONS CORPORATION, KANAGAWA (JP)

(72) Inventor: YASUO KANDA, KANAGAWA (JP)

(21) Appl. No.: 19/167,280

(22) PCT Filed: Mar. 25, 2024
(86) PCT No.: PCT/JP2024/011589

§ 371 Date: Sep. 19, 2025

(30) Foreign Application Priority Data
Apr. 7, 2023 (JP) 2023-062471

(51) Int. Cl. H10W 20/43; G11C 11/16; H10B 61/00; H10N 50/10; H10W 20/41

(52) U.S. Cl. CPC H10W 20/43; G11C 11/1697; H10B 61/22; H10W 20/427; H10W 20/435; H10N 50/10

(57) ABSTRACT

To achieve miniaturization of a memory circuit. The memory circuit includes a memory cell and an applied voltage adjustment unit. The memory cell included in the memory circuit is equipped with: a resistive element; and a cell transistor that is connected to one end of the resistive element and controls a voltage to be applied to the resistive element. The applied voltage adjustment unit included in the memory circuit adjusts an impedance of an impedance element connected in series to a power supply line that supplies power to the memory cell so as to adjust the voltage to be applied to the memory cell.

### FIELD

The present disclosure relates to a memory circuit, a semiconductor device, and an electronic device.

### BACKGROUND

Currently used memory includes resistive memory in which a resistive element whose resistance value changes according to an applied voltage is employed as a nonvolatile storage element. In this resistive memory, it is necessary to apply different voltages to memory cells at the time of writing and reading. There is a proposed resistive memory using a voltage generation circuit, which converts the voltage supplied from the outside to generate a voltage necessary for the operation of the resistive memory (refer to Patent Literature 1, for example). Such a voltage generation circuit uses a charge pump circuit.

### CITATION LIST

### Patent Literature

Patent Literature 1: JP 2018-092696 A

### SUMMARY

### Technical Problem

However, the above-described conventional technique uses a charge pump circuit and thus has a problem of difficulty in miniaturizing the circuit. This is because the charge pump circuit includes a plurality of capacitors, increasing a circuit area.

In view of this, the present disclosure proposes a miniaturized memory circuit, and a semiconductor device and an electronic device using the miniaturized memory circuit.

### Solution to Problem

A memory circuit according to the present disclosure includes a memory cell and an applied voltage adjustment unit. The memory cell equips with a resistive element and a cell transistor. The cell transistor is connected to one end of the resistive element and configured to control a voltage to be applied to the resistive element. The applied voltage adjustment unit is configured to adjust impedance of an impedance element connected in series to a power supply line that supplies power to the memory cell so as to adjust a voltage to be applied to the memory cell.

### BRIEF DESCRIPTION OF DRAWINGS

FIG. 1 is a diagram illustrating a configuration example of a computer system according to an embodiment of the present disclosure.

FIG. 2 is a diagram illustrating a configuration example of the memory array according to the embodiment of the present disclosure.

FIG. 3 is a diagram illustrating a configuration example of the memory cell array according to the embodiment of the present disclosure.

FIG. 4 is a diagram illustrating a configuration example of an applied voltage adjustment unit according to the embodiment of the present disclosure.

FIG. 5 is a diagram illustrating a configuration example of a memory cell according to a first embodiment of the present disclosure.

FIG. 6A is a cross-sectional view illustrating a configuration example of the memory cell according to the first embodiment of the present disclosure.

FIG. 6B is a cross-sectional view illustrating a configuration example of the memory cell according to the first embodiment of the present disclosure.

FIG. 7A is a diagram illustrating a configuration example of a memory cell according to a second embodiment of the present disclosure.

FIG. 7B is a diagram illustrating a configuration example of the memory cell according to the second embodiment of the present disclosure.

FIG. 8A is a diagram illustrating another configuration example of the memory cell according to the second embodiment of the present disclosure.

FIG. 8B is a diagram illustrating another configuration example of the memory cell according to the second embodiment of the present disclosure.

FIG. 9A is a diagram illustrating another configuration example of the memory cell according to the second embodiment of the present disclosure.

FIG. 9B is a diagram illustrating another configuration example of the memory cell according to the second embodiment of the present disclosure.

### DESCRIPTION OF EMBODIMENTS

Embodiments of the present disclosure will be described below in detail with reference to the drawings. The description will be given in the following order. Note that, in each of the following embodiments, the same parts are denoted by the same reference symbols, and a repetitive description thereof will be omitted.
1. First embodiment
2. Second embodiment

### 1. First Embodiment

### [Configuration of Computer System]

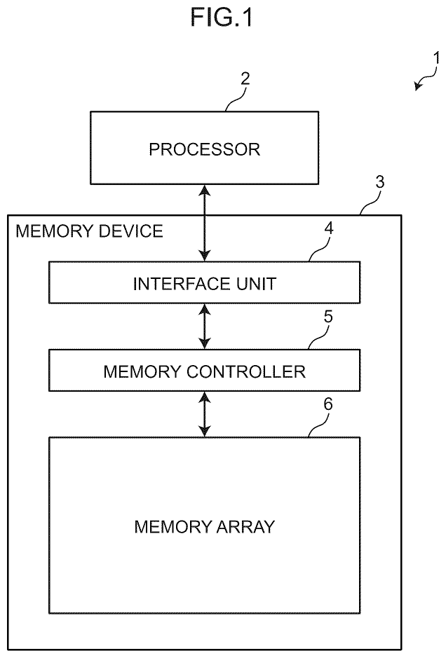

FIG. 1 is a diagram illustrating a configuration example of a computer system according to an embodiment of the present disclosure. The drawing is a block diagram illustrating a configuration example of a computer system 1. The computer system 1 includes a processor 2 and a memory device 3. The computer system 1 is an example of an “electronic device” of the present disclosure. The processor 2 is an example of a “host processor” of the present disclosure.

The processor 2 performs data communication with the memory device 3. The processor 2 issues data write and read commands to the memory device 3.

The memory device 3 holds data. The memory device 3 holds data based on a write command from the processor 2, and outputs the held data to the processor 2 based on a read command. The memory device 3 includes an interface unit 4, a memory controller 5, and a memory array 6. The memory device 3 is an example of a “semiconductor device” of the present disclosure.

The interface unit 4 is an interface that communicates with the processor 2. Examples of interfaces usable as an interface to connect to the processor 2 include SATA, PCI Express, and USB.

The memory controller 5 performs overall control of the memory device 3. The memory controller 5 receives a command from the processor 2 and controls data write and read based on the received command. The memory controller 5 outputs write and read commands and addresses, and write target data to the memory array 6. In addition, the memory controller 5 outputs a read command and thereafter receives read data from the memory array 6.

The memory array 6 includes a plurality of memory cells (memory cells 100 to be described below) and stores (holds) data.

### [Configuration of Memory Array]

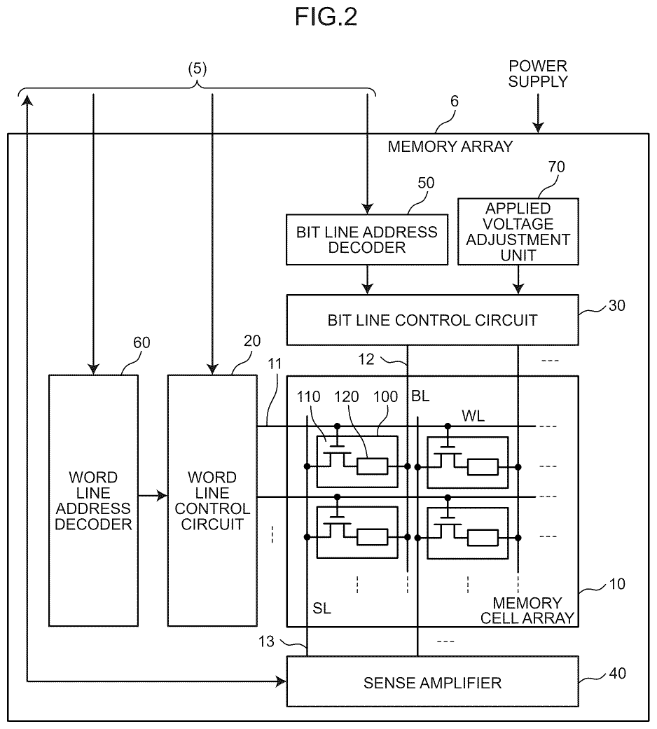

FIG. 2 is a diagram illustrating a configuration example of the memory array according to the embodiment of the present disclosure. The drawing is a block diagram illustrating a configuration example of a memory array 6. The memory array 6 includes a memory cell array 10, a word line address decoder 60, a word line control circuit 20, a bit line address decoder 50, a bit line control circuit 30, and a sense amplifier 40. The memory array 6 further includes an applied voltage adjustment unit 70.

The memory cell array 10 is constituted with a two-dimensional matrix including memory cells 100 storing data. The memory cell 100 includes a magnetoresistive effect element 120 and a cell transistor 110.

The magnetoresistive effect element 120 is a resistive element. The magnetoresistive effect element 120 can be implemented by using a magnetoresistive effect element such as a magnetic tunnel junction (MTJ) element, for example. The MTJ element is an element in which a non-magnetic insulating layer is disposed between two ferromagnetic layers, and is an element in which a resistance value changes according to a magnetization direction of the two ferromagnetic layers. The MTJ element is in a high resistance state in a case where the magnetization directions of the two ferromagnetic layers are different, and is in a low resistance state in a case where the magnetization directions are the same. The state in which the magnetization directions are the same is referred to as a parallel state, while a state in which the magnetization directions are different is referred to as an anti-parallel state. The direction of the magnetization can be changed by applying a write voltage to the MTJ element. For example, it is possible to store 1-bit data by associating the values “0” and “1” with the low resistance state and the high resistance state of the MTJ element, respectively. The values “0” and “1” can also be referred to as a low level voltage (L) and a high level voltage (H), respectively.

The cell transistor 110 is an element that is connected to one end of the magnetoresistive effect element 120 and controls application of a voltage to the magnetoresistive effect element 120. The cell transistor 110 can be implemented by adopting an n-channel MOS transistor, for example.

The memory cell 100 is connected to a word line 11 and a bit line 12, being the lines that transmit a control signal. The word line 11 is formed with a plurality of word lines WL. The bit line 12 is formed with a plurality of bit lines BL. The memory cell 100 further includes a source line 13 disposed to transmit a signal from the magnetoresistive effect element 120. The source line 13 is formed with a plurality of source lines SL. The memory cell array 10 has the plurality of word lines WL disposed in the row direction, and the plurality of bit lines BL and source lines SL disposed in the column direction.

The word line address decoder 60 selects the word line WL of the memory cell array 10 based on a control signal from the memory controller 5.

The word line control circuit 20 outputs a control signal to the word line WL selected by the word line address decoder 60. As described below, the word line control circuit 20 includes a word line driver 21.

The bit line address decoder 50 selects the bit line BL of the memory cell array 10 based on a control signal from the memory controller 5.

The bit line control circuit 30 outputs a control signal to the bit line BL selected by the bit line address decoder 50. In addition, at the time of reading, the bit line control circuit 30 controls reading from the memory cell 100 at the intersection of the selected word line WL and bit line BL. In addition, at the time of writing, the bit line control circuit 30 controls writing to the memory cell 100 at the intersection of the selected word line WL and bit line BL.

The sense amplifier 40 detects a current flowing through the memory cell 100 at the time of reading, thereby reading data. The data that has been read is output to the memory controller 5. The sense amplifier 40 applies a write voltage to the memory cell 100 at the time of writing.

Writing to the memory cell 100 is performed when the storage data of the memory cell 100 is different from the write data. That is, data is read from the memory cell 100, and the data that has been read is compared with the write data. Writing is performed when pieces of data are different as a result of the comparison. In this case, the writing can be performed by inverting the storage data of the memory cell 100. That is, writing can be performed by inverting the storage state of the magnetoresistive effect element 120. The inversion of the storage state of the magnetoresistive effect element 120 can be performed by applying a write voltage of a predetermined voltage to the magnetoresistive effect element 120.

Reading can be performed by applying a predetermined read voltage to the magnetoresistive effect element 120 of the memory cell 100 and detecting a current flowing through the memory cell 100. The read voltage is preferably a voltage different, in polarity, from the write voltage.

The applied voltage adjustment unit 70 adjusts a voltage to be applied to the memory cell 100. The applied voltage adjustment unit 70 adjusts the impedance of an impedance element connected in series to a power supply line that supplies power to the memory cell 100 so as to adjust the voltage to be applied to the memory cell 100. As described above, different voltages are applied to the memory cell 100 in accordance with writing or reading. The applied voltage adjustment unit 70 is a circuit that generates a voltage necessary for the operation of the memory cell 100 based on a power supply voltage supplied from the outside to the memory array 6. Details of the configuration of the applied voltage adjustment unit 70 will be described below.

### [Configuration of Memory Cell Array]

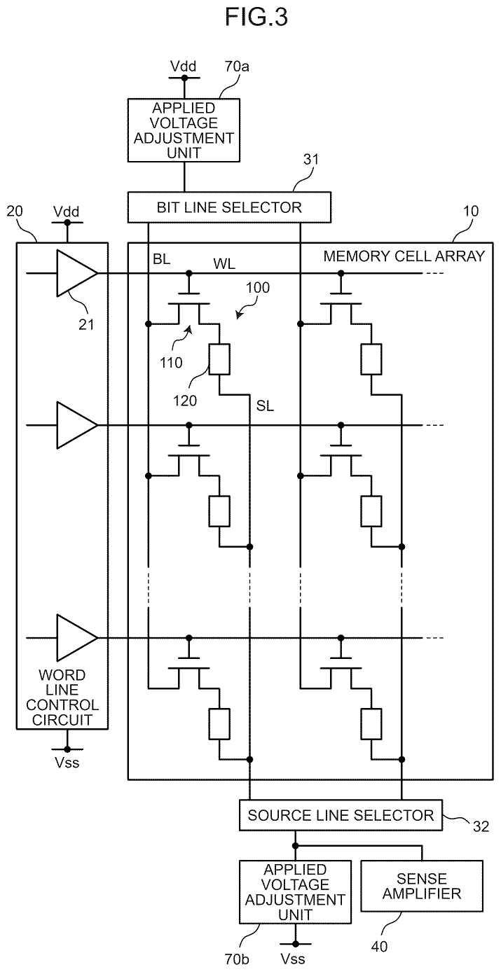

FIG. 3 is a diagram illustrating a configuration example of the memory cell array according to the embodiment of the present disclosure. The drawing is a circuit diagram illustrating a configuration example of the memory cell array 10. The drawing also illustrates applied voltage adjustment units 70a and 70b, a bit line selector 31, a source line selector 32, the word line control circuit 20, the word line driver 21, and the sense amplifier 40. The drawing further illustrates a power supply line Vdd and a power supply line Vss. The power supply line Vdd corresponds to a power supply line on the source side, while the power supply line Vss corresponds to a power supply line on the sink side. The power supply line Vdd and the power supply line Vss supply a voltage of 2.5 V, for example. The circuit including the memory cell 100 and the applied voltage adjustment units 70a and 70b in the drawing is an example of a “memory circuit” of the present disclosure.

The bit line selector 31 is controlled by the bit line control circuit 30 to select the bit line BL. The source line selector 32 is controlled by the bit line control circuit 30 to select the source line SL.

The cell transistor 110 has its drain connected to the bit line BL and its gate connected to the word line WL. The source of the cell transistor 110 is connected to one end of the magnetoresistive effect element 120. Another end of the magnetoresistive effect element 120 is connected to the source line SL.

The applied voltage adjustment unit 70a is connected to the power supply line Vdd to adjust the voltage of the power supply line Vdd. The voltage adjusted by the applied voltage adjustment unit 70a is supplied to the bit line BL via the bit line selector 31.

The applied voltage adjustment unit 70b is connected to the power supply line Vss to adjust the voltage of the power supply line Vss. The voltage adjusted by applied voltage adjustment unit 70b is output to source line SL via the source line selector 32.

The word line WL is connected to the output of the word line driver 21. The bit line BL is connected to the bit line selector 31. The source line SL is connected to the sense amplifier 40 via the source line selector 32. By applying a voltage across the bit line BL and the source line SL and applying an on-voltage for conducting the cell transistor 110 to the word line WL, it is possible to apply the voltage for reading or writing to the magnetoresistive effect element 120.

The voltage to be applied to the magnetoresistive effect element 120 of the memory cell 100 is set to 1.4 V when writing from the value “1” to the value “0” and set to 1.8 V when writing from the value “0” to the value “1”, for example. This write voltage can be adjusted by the ambient temperature.

On the other hand, the circuit of the memory array 6 operates on a voltage of 2.5 V supplied by the power supply line Vdd and the power supply line Vss. By allowing the memory array 6 to include a circuit that generates the applied voltage of the magnetoresistive effect element 120 based on the voltage of 2.5 V, convenience can be improved.

In a conventional memory device, a charge pump circuit is disposed to convert a power supply voltage to generate a voltage to be applied to the memory cell 100. However, the charge pump circuit needs a capacitor of a relatively large capacity, increasing the occupied area. Therefore, the memory array 6 including the charge pump circuit has a problem of an increase in the chip size. In addition, the charge pump circuit takes a long time until the output voltage is stabilized, leading to a problem of delayed activation.

In view of these, the applied voltage adjustment unit 70 is disposed to adjust the power supply voltage to a voltage necessary for operations such as writing to the memory cell 100. Omission of the charge pump circuit can reduce the chip size of the memory array 6. As described below, since the applied voltage adjustment unit 70 is a dropper type circuit, there will be a problem of an increased loss when there is a large difference between the voltage of the power supply line Vdd and the voltage applied to the memory cell 100. Therefore, instead of a thin film transistor normally used as the cell transistor 110 of the memory cell 100, a thick film transistor having a relatively high breakdown voltage is used to reduce the difference between the voltage of the power supply line Vdd and the voltage applied to the memory cell 100. This can decrease the loss in the applied voltage adjustment unit 70.

The thick film transistor is a transistor including a gate oxide film having a film thickness exceeding 2 nm. Using such a thick film transistor for the cell transistor 110 increases the area of the memory cell 100, also increasing the occupied area of the memory cell array 10. However, the applied voltage adjustment unit 70 smaller in size than the charge pump circuit is used, making it possible to reduce the overall size of the memory array 6.

The configuration of the memory circuit is not limited to this example. For example, it is allowable to have a configuration omitting one of the applied voltage adjustment units 70a and 70b.

### [Applied Voltage Adjustment Unit]

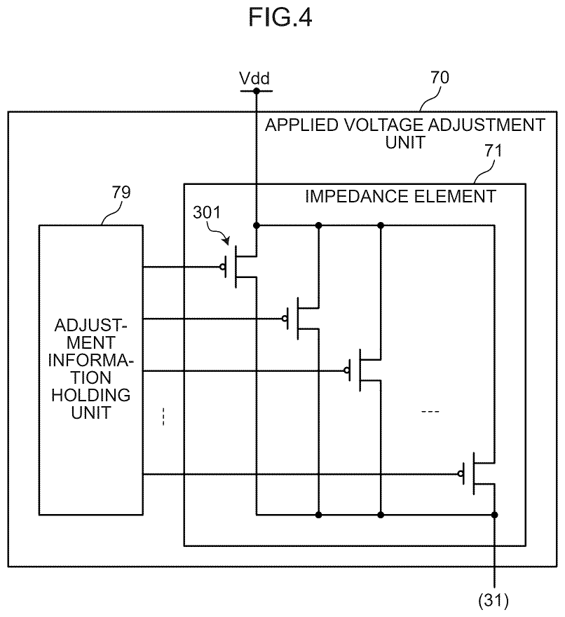

FIG. 4 is a diagram illustrating a configuration example of the applied voltage adjustment unit according to the embodiment of the present disclosure. The figure is a circuit diagram illustrating a configuration example of the applied voltage adjustment unit 70. The applied voltage adjustment unit 70 in the drawing corresponds to the applied voltage adjustment unit 70a in FIG. 3. The applied voltage adjustment unit 70 includes an impedance element 71 and adjustment information holding unit 79.

The impedance element 71 is an element to be connected in series to the power supply line (power supply line Vdd) to cause a voltage drop. The impedance element 71 in FIG. 4 is an example of being formed with a plurality of MOS transistors 301 connected in parallel. The MOS transistor 301 can be implemented by using a p-channel MOS transistor. The impedance can be adjusted by switching conduction and non-conduction of the plurality of MOS transistors 301.

The adjustment information holding unit 79 holds adjustment information, which is information regarding conduction and non-conduction of the plurality of MOS transistors 301 of the impedance element 71. Based on the adjustment information, the adjustment information holding unit 79 applies an on-voltage to the gate of each of the plurality of MOS transistors 301.

By connecting the applied voltage adjustment unit 70 between the power supply line Vdd and the load (memory cell 100) to cause a voltage drop, it is possible to decrease the power supply voltage. In addition, by adjusting the impedance of the impedance element 71, the power supply voltage supplied by the power supply line Vdd can be adjusted to a desired voltage.

### [Configuration of Memory Cell]

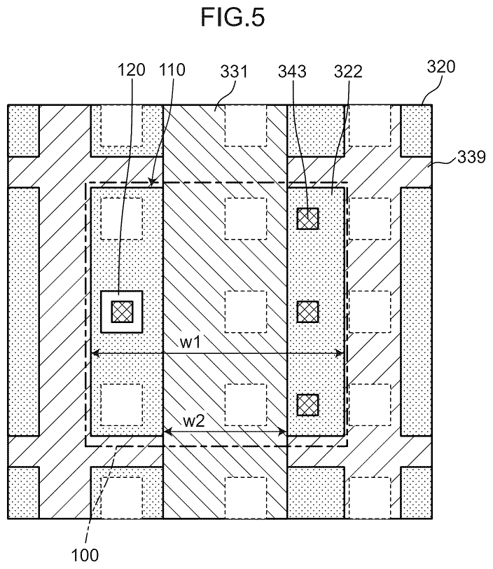

FIG. 5 is a diagram illustrating a configuration example of a memory cell according to a first embodiment of the present disclosure. The figure is a plan view illustrating a configuration example of the memory cell 100 illustrated in FIG. 3. The figure is a layout diagram of the memory cells 100 arranged on a semiconductor substrate 320. A rectangle drawn with a one-dot chain line in the figure represents a region of the cell transistor 110. The memory cell 100 is formed in an active region 322 of the semiconductor substrate 320. The active region 322 is a region where a drain region, a source region, and a channel of the cell transistor 110 can be formed. The active region 322 is separated from other memory cells 100 by a separator 339. The separator 339 can be formed with Shallow Trench Isolation (STI), for example.

On an upper layer of the active region 322, gate wiring 331 is disposed via a gate oxide film. The active region 322 below the gate wiring 331 is a portion where a channel is formed. The drain region is formed in the active region 322 on the left side in FIG. 5 of the gate wiring 331, while the source region is formed in the active region 322 on the right side in FIG. 5 of the gate wiring 331. The source region is connected with a contact plug 343. An open rectangle in FIG. 5 represents the magnetoresistive effect element 120. The magnetoresistive effect element 120 is connected to the drain region of the cell transistor 110 by the contact plug 343.

“w1” in FIG. 5 represents an interval between a region where the contact plug 343 of the drain of the cell transistor 110 is to be connected and a region where the contact plug 343 of the source is to be connected. “w2” represents a gate width of the cell transistor 110. As illustrated in FIG. 5, w1 can be set to be greater than w2. As illustrated in FIG. 5, the cell transistor 110 is formed to be larger in area than the separator 339.

The rectangle in a dashed line in FIG. 5 also represents the magnetoresistive effect element 120. The magnetoresistive effect element 120 in the dashed line is in a floating state and corresponds to a dummy element as the magnetoresistive effect element 120. The dummy magnetoresistive effect element 120 can be omitted.

### [Configuration of Memory Cell]

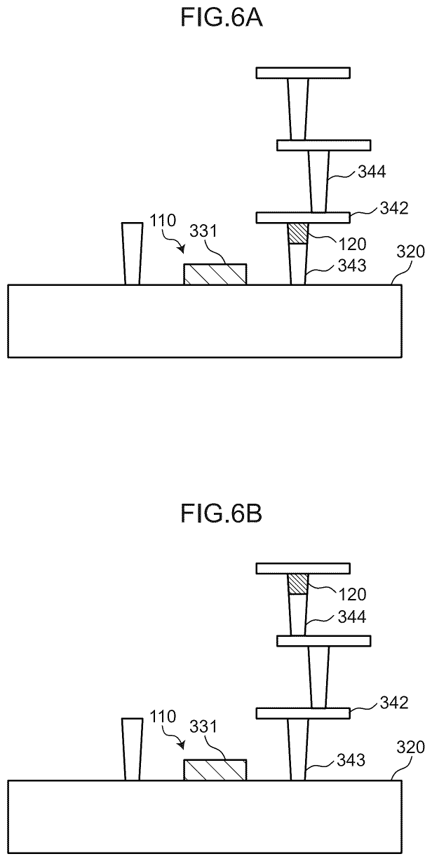

FIGS. 6A and 6B are cross-sectional views each illustrating a configuration example of the memory cell according to the first embodiment of the present disclosure. FIGS. 6A and 6B are schematic cross-sectional views illustrating a configuration example of the memory cell 100 illustrated in FIG. 3. FIGS. 6A and 6B illustrate the cell transistor 110 formed on the semiconductor substrate 320, the gate wiring 331, wiring 342 included in the wiring region formed on the upper layer of the semiconductor substrate 320, the contact plug 343, and a via plug 344. The via plug 344 connects portions of the wiring 342 located in different layers. The contact plug 343 in FIGS. 6A and 6B is connected to the drain and the source of the cell transistor 110. In FIGS. 6A and 6B, the magnetoresistive effect element 120 is disposed in a wiring region formed on an upper layer of the semiconductor substrate 320.

FIG. 6A illustrates an example in which the magnetoresistive effect element 120 is disposed between the contact plug 343 and the wiring 342. FIG. 6B illustrates an example in which the magnetoresistive effect element 120 is disposed between the via plug 344 and the wiring 342.

### [Application Example to OTP Memory]

The memory circuit in FIG. 3 may be formed as One Time Programmable (OTP) memory. The OTP memory is memory to which writing can be performed only once. Specifically, the OTP memory can be formed by destructing a cell transistor 112 after writing to the memory cell 100. The destruction of the cell transistor 112 can be performed by adjusting the output voltage of the applied voltage adjustment unit 70 to a high voltage and applying the adjusted voltage to the cell transistor 112 to destruct the gate oxide film.

In this manner, in the first embodiment of the present disclosure, the memory circuit can be reduced in size by disposing the applied voltage adjustment unit 70 instead of the charge pump circuit.

### 2. Second Embodiment

Variations of the memory cell array 10 will be described.

### [Configuration of Memory Cell]

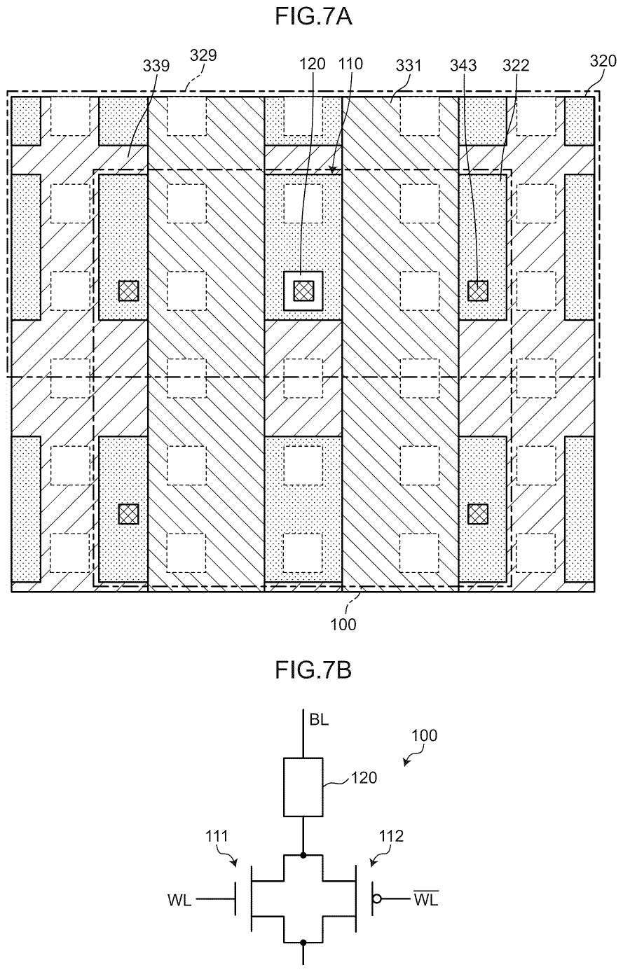

FIGS. 7A and 7B are diagrams each illustrating a configuration example of a memory cell according to a second embodiment of the present disclosure. FIG. 7A is a plan view illustrating a configuration example of the memory cell 100 similarly to FIG. 5. FIG. 7B is a circuit diagram illustrating a configuration example of the memory cell 100 of FIG. 7A. The memory cell 100 of FIG. 7A includes cell transistors 111 and 112. The cell transistor 111 can be implemented by adopting an n-channel MOS transistor. The cell transistor 112 can be implemented by adopting a p-channel MOS transistor.

In FIG. 7A, a rectangle drawn with a two-dot chain line represents an n-well region 329. The cell transistor 112 can be disposed in the active region 322 of the n-well region 329. The cell transistor 111 is disposed in the active region 322 on the lower side of FIG. 7A.

### [Another Configuration of Memory Cell]

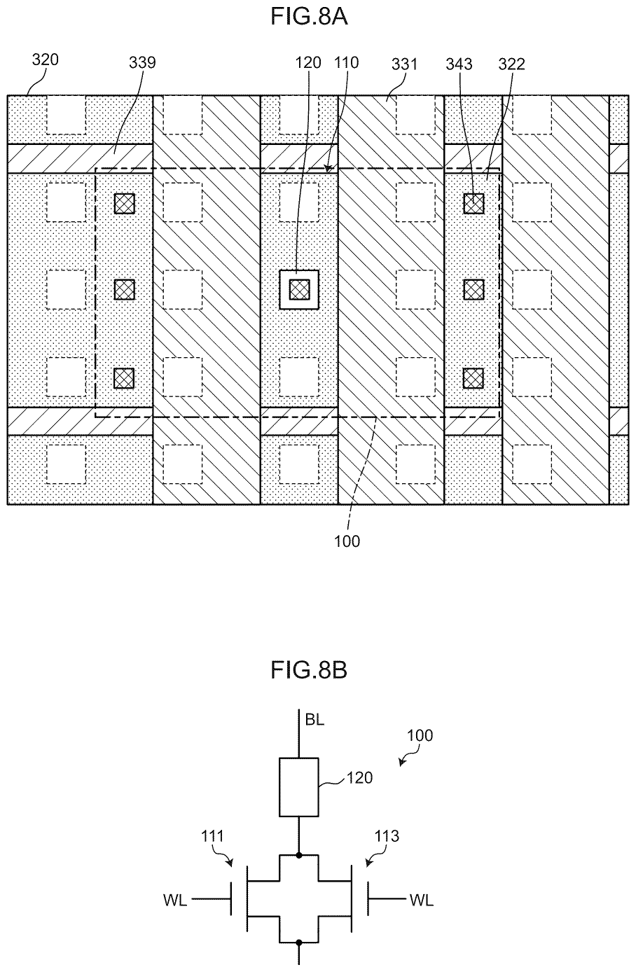

FIGS. 8A and 8B are diagrams each illustrating another configuration example of the memory cell according to the second embodiment of the present disclosure. FIG. 8A is a plan view illustrating a configuration example of the memory cell 100 similarly to FIG. 7A. FIG. 8B is a circuit diagram illustrating a configuration example of the memory cell 100 of FIG. 8A. The memory cell 100 of FIG. 8B includes cell transistors 111 and 113. The cell transistor 113 can be implemented by adopting an n-channel MOS transistor. The separator 339 in FIG. 8A is formed in a slit shape. The memory cell 100 in FIG. 8A is separated by the gate wiring 331 from another memory cell 100 adjacent in the lateral direction.

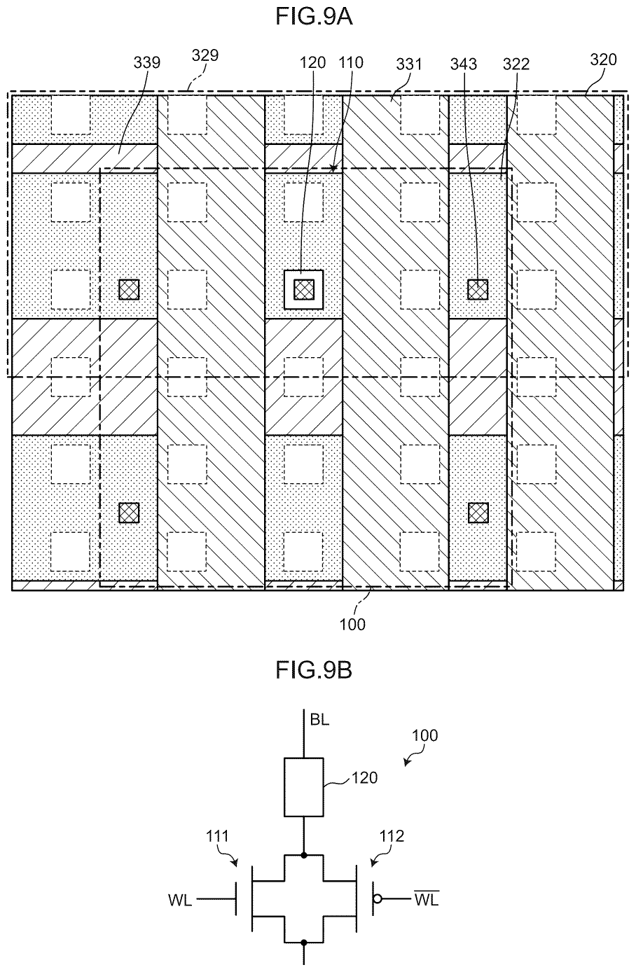

FIGS. 9A and 9B are diagrams each illustrating another configuration example of the memory cell according to the second embodiment of the present disclosure. FIG. 9A is a plan view illustrating a configuration example of the memory cell 100 similarly to FIG. 8A. FIG. 9B is a circuit diagram illustrating a configuration example of the memory cell 100 of FIG. 9A. The memory cell 100 of FIG. 9B includes cell transistors 111 and 112. In FIG. 9A, an n-well region 329 similar to that in FIG. 7A is formed. The cell transistor 112 is disposed in this region.

The configuration of the memory circuit other than this is similar to the configuration of the memory circuit according to the first embodiment of the present disclosure, and thus the description thereof will be omitted.

The embodiments of the present disclosure have been described above. However, the technical scope of the present disclosure is not limited to the above-described embodiments, and various modifications can be made without departing from the scope of the present disclosure. Moreover, it is allowable to combine the components across different embodiments and modifications as appropriate.

The effects described in the present specification are merely examples, and thus, there may be other effects, not limited to the exemplified effects.

The present technology can also have the following configurations.

(1) A memory circuit comprising:
a memory cell, the memory cell being equipped with a resistive element and a cell transistor, the cell transistor being connected to one end of the resistive element and configured to control a voltage to be applied to the resistive element; and
an applied voltage adjustment unit, the applied voltage adjustment unit configured to adjust impedance of an impedance element connected in series to a power supply line that supplies power to the memory cell so as to adjust a voltage to be applied to the memory cell.

(2) The memory circuit according to the above (1), wherein the memory cell includes a magnetoresistive effect element as the resistive element.

(3) The memory circuit according to the above (1), wherein the applied voltage adjustment unit is connected to either a power supply line connected to another end of the resistive element in the memory cell or a power supply line connected to the cell transistor.

(4) The memory circuit according to the above (1), further comprising a plurality of the applied voltage adjustment units, each of the applied voltage adjustment units being connected to each of a power supply line connected to another end of the resistive element in the memory cell and a power supply line connected to the cell transistor.

(5) The memory circuit according to any one of the above (1) to (4), wherein the resistive element is disposed on an upper layer of the cell transistor.

(6) The memory circuit according to any one of the above (1) to (5), wherein the cell transistor is formed with a MOS transistor.

(7) The memory circuit according to the above (6), wherein the cell transistor includes a gate oxide film having a film thickness exceeding 2 nm.

(8) The memory circuit according to the above (6), wherein the cell transistor has a shape in which an interval between a region connecting a drain contact plug and a region connecting a source contact plug is larger than a gate width.

(9) The memory circuit according to any one of the above (1) to (8), further comprising a separator disposed on a semiconductor substrate on which the cell transistor is disposed and configured to separate the cell transistor,
wherein the cell transistor is larger in area than the separator in plan view.

(10) The memory circuit according to any one of the above (1) to (9), wherein the applied voltage adjustment unit adjusts the voltage to be applied to the memory cell to a voltage that destructs a gate oxide film of the cell transistor.

(11) A semiconductor device comprising:
a memory circuit; and
a control unit that controls the memory circuit, the memory
a memory cell being equipped with a resistive element and a cell transistor, the cell transistor being connected to one end of the resistive element and configured to control a voltage to be applied to the resistive element; and
an applied voltage adjustment unit, the applied voltage adjustment unit configured to adjust impedance of an impedance element connected in series to a power supply line that supplies power to the memory cell so as to adjust a voltage to be applied to the memory cell.

(12) An electronic device comprising:
a memory device; and
a host processor configured to perform data communication with the memory device,
the memory device including:
a memory circuit; and
a control unit that controls the memory circuit, the memory circuit including:
a memory cell being equipped with a resistive element and a cell transistor, the cell transistor being connected to one end of the resistive element and configured to control a voltage to be applied to the resistive element; and
an applied voltage adjustment unit, the applied voltage adjustment unit configured to adjust impedance of an impedance element connected in series to a power supply line that supplies power to the memory cell so as to adjust a voltage to be applied to the memory cell.

### REFERENCE SIGNS LIST

1 COMPUTER SYSTEM
2 PROCESSOR
3 MEMORY DEVICE
6 MEMORY ARRAY
10 MEMORY CELL ARRAY
70, 70a, 70b APPLIED VOLTAGE ADJUSTMENT UNIT
71 IMPEDANCE ELEMENT
100 MEMORY CELL
110 to 113 CELL TRANSISTOR
120 MAGNETORESISTIVE EFFECT ELEMENT

1. A memory circuit comprising:
a memory cell, the memory cell being equipped with a resistive element and a cell transistor, the cell transistor being connected to one end of the resistive element and configured to control a voltage to be applied to the resistive element; and
an applied voltage adjustment unit, the applied voltage adjustment unit configured to adjust impedance of an impedance element connected in series to a power supply line that supplies power to the memory cell so as to adjust a voltage to be applied to the memory cell.

2. The memory circuit according to claim 1, wherein the memory cell includes a magnetoresistive effect element as the resistive element.

3. The memory circuit according to claim 1, wherein the applied voltage adjustment unit is connected to either a power supply line connected to another end of the resistive element in the memory cell or a power supply line connected to the cell transistor.

4. The memory circuit according to claim 1, further comprising a plurality of the applied voltage adjustment units, each of the applied voltage adjustment units being connected to each of a power supply line connected to another end of the resistive element in the memory cell and a power supply line connected to the cell transistor.

5. The memory circuit according to claim 1, wherein the resistive element is disposed on an upper layer of the cell

6. The memory circuit according to claim 1, wherein the cell transistor is formed with a MOS transistor.

7. The memory circuit according to claim 6, wherein the cell transistor includes a gate oxide film having a film thickness exceeding 2 nm.

8. The memory circuit according to claim 6, wherein the cell transistor has a shape in which an interval between a region connecting a drain contact plug and a region connecting a source contact plug is larger than a gate width.

9. The memory circuit according to claim 1, further comprising a separator disposed on a semiconductor substrate on which the cell transistor is disposed and configured to separate the cell transistor,
wherein the cell transistor is larger in area than the separator in plan view.

10. The memory circuit according to claim 1, wherein the applied voltage adjustment unit adjusts the voltage to be applied to the memory cell to a voltage that destructs a gate oxide film of the cell transistor.

11. A semiconductor device comprising:
a memory circuit; and
a control unit that controls the memory circuit, the memory circuit including:
a memory cell being equipped with a resistive element and a cell transistor, the cell transistor being connected to one end of the resistive element and configured to control a voltage to be applied to the resistive element; and
an applied voltage adjustment unit, the applied voltage adjustment unit configured to adjust impedance of an impedance element connected in series to a power supply line that supplies power to the memory cell so as to adjust a voltage to be applied to the memory cell.

12. An electronic device comprising:
a memory device; and
a host processor configured to perform data communication with the memory device,
the memory device including:
a memory circuit; and
a control unit that controls the memory circuit, the memory circuit including:
a memory cell being equipped with a resistive element and a cell transistor, the cell transistor being connected to one end of the resistive element and configured to control a voltage to be applied to the resistive element; and
an applied voltage adjustment unit, the applied voltage adjustment unit configured to adjust impedance of an impedance element connected in series to a power supply line that supplies power to the memory cell so as to adjust a voltage to be applied to the memory cell.
